(19) United States
(12) Patent Application Publication
(10) Pub. No.: US 2010/0163104 A1
(43) Pub. Date: Jul. 1, 2010

(54) SOLAR CELL

(75) Inventor: Yu-Chu Tseng, Hsinchu (TW)

Correspondence Address: KIRTON AND MCCONKIE, 60 EAST SOUTH TEMPLE,, SUITE 1800, SALT LAKE CITY, UT, 84111, US

(73) Assignee: MOSEL VITELIC INC., Hsinchu (TW)

(21) Appl. No.: 12/632,650

(22) Filed: Dec. 7, 2009

(30) Foreign Application Priority Data
Dec. 31, 2008 (TW) 097151598

(51) Int. Cl. H01L 31/00

(52) U.S. Cl. 136/256

(57) ABSTRACT

A solar cell includes a semiconductor substrate, an emitter layer, an anti-reflective coating, a first electrode, a second electrode, and a first light conversion layer. The emitter layer is formed on a light-receiving side of the semiconductor substrate. A p-n junction is formed between the emitter layer and the semiconductor substrate. The anti-reflective coating is formed on the emitter layer. The first electrode is connected to the emitter layer. The second electrode is formed on a back-lighted side of the semiconductor substrate. The first light conversion layer is formed on the anti-reflective coating. The first light conversion layer absorbs a first light with a first wavelength and emits a second light with a second wavelength, thereby performing a photoelectric converting operation.

### FIELD OF THE INVENTION

The present invention relates to a photoelectric component, and more particularly to a solar cell capable of utilizing the light in the UV-spectral range and the IR-spectral range to generate electrical energy.

### BACKGROUND OF THE INVENTION

Recently, the ecological problems resulted from fossil fuels such as petroleum and coal have been greatly aware all over the world. Consequently, there are growing demands on clean energy. Among various alternative energy sources, a solar cell is expected to replace fossil fuel as a new energy source because it provides clean energy without depletion and is easily handled. A solar cell is a device that converts light energy into electrical energy. The procedure of turning solar energy into electrical energy is called the photovoltaic (PV) effect. With the increasing development of solar cell techniques, a bifacial solar cell has been proposed. The bifacial solar cell can accept sunlight from both surfaces and convert light energy into electrical energy and thus the conversion efficiency is increased.

Hereinafter, a conventional process of fabricating a solar cell is illustrated as follows with reference to FIGS. 1A˜1D.

First of all, as shown in FIG. 1A, a p-type semiconductor substrate 11 is provided. Next, concave and convex patterns with a minute pyramidal shape called as a texture are formed on the surface of the semiconductor substrate 11 in order to improve light absorption and reduce light reflectivity. The texture structure is very minute and thus not shown in FIG. 1A.

Next, as shown in FIG. 1B, an n-type dopant source diffuses into the substrate at high temperature, thereby forming an n-type emitter layer 12 (also referred as a diffusion layer) on the light-receiving side S1 (or front side) and a p-n junction interface between the p-type semiconductor substrate 11 and the emitter layer 12. At this time, a phosphosilicate glass (PSG) layer 13 is formed on the emitter layer 12.

Next, as shown in FIG. 1C, the PSG layer 13 is removed to expose the emitter layer 12 by an etching procedure. Then, an anti-reflective coating 14, which is made of for example silicon nitride (SiNx), is formed on the emitter layer 12 in order to reduce light reflectivity and passivate the emitter layer 12.

Next, as shown in FIG. 1D, an aluminum conductor layer and a silver conductor layer are respectively formed on the back-lighted side S2 (or back side) and the light-receiving side S1 by screen printing. Afterwards, by firing the silver conductor layer, a first electrode 15 is formed on the light-receiving side S1. Similarly, by firing the aluminum conductor layer, a back surface field (BSF) layer 16 and a second electrode 17 are formed on the back-lighted side S2, thereby completing the solar cell.

Although the conventional monofacial solar cell or bifacial solar cell has good PV effect, there are still some drawbacks. For example, the incident light that is received and converted into electrical energy falls in a specified spectral range. For most conventional solar cells, the usable wavelength of the sunlight is ranged from 400 nm to 1,100 nm. The wavelength range of every solar cell is dependent on the microcrystalline silicon material and the light-absorption material. Generally, the UV light with a wavelength smaller than 400nm which generates e-h pairs in heavy emitter layer called death layer of conventional solar cell and the IR light with a wavelength greater than 1,100 nm fail to be adsorbed by the conventional solar cell and converted into electrical energy. In other words, the conventional solar cell fails to utilize the light in the UV-spectral range and the IR-spectral range and thus the performance of the conventional solar cell is unsatisfied.

Therefore, there is a need of providing an improved solar cell so as to obviate the drawbacks encountered from the prior art.

### SUMMARY OF THE INVENTION

It is an object of the present invention to provide a solar cell capable of utilizing the light in the UV-spectral range and the IR-spectral range to generate electrical energy.

In accordance with an aspect of the present invention, there is provided a solar cell. The solar cell includes a semiconductor substrate, an emitter layer, an anti-reflective coating, a first electrode, a second electrode, and a first light conversion layer. The emitter layer is formed on a light-receiving side of the semiconductor substrate. A p-n junction is formed between the emitter layer and the semiconductor substrate. The anti-reflective coating is formed on the emitter layer. The first electrode is connected to the emitter layer. The second electrode is formed on a back-lighted side of the semiconductor substrate. The first light conversion layer is formed on the anti-reflective coating. The first light conversion layer absorbs a first light with a first wavelength and emits a second light with a second wavelength, thereby performing a photoelectric converting operation.

In accordance with another aspect of the present invention, there is provided a solar cell. The solar cell includes a semiconductor substrate, an emitter layer, an anti-reflective coating, a first electrode, a second electrode, and a second light conversion layer. The emitter layer is formed on a light-receiving side of the semiconductor substrate. A p-n junction is formed between the emitter layer and the semiconductor substrate. The anti-reflective coating is formed on the emitter layer. The first electrode is connected to the emitter layer. The second electrode is formed on a back-lighted side of the semiconductor substrate. The second light conversion layer is formed on the back-lighted side of the semiconductor substrate. The second light conversion layer absorbs a first light with a first wavelength and emits a second light with a second wavelength, thereby performing a photoelectric converting operation.

In accordance with a further aspect of the present invention, there is provided a bifacial solar cell. The bifacial solar cell includes a semiconductor substrate, an emitter layer, an anti-reflective coating, a first electrode, a second electrode, a first light conversion layer, and a second light conversion layer. The emitter layer is formed on a first side or a second side or both sides of the semiconductor substrate. A p-n junction is formed between the emitter layer and the semiconductor substrate. The anti-reflective coating is formed on the emitter layer. The first electrode is connected to the emitter layer. The second electrode is connected to the semiconductor substrate. The first light conversion layer is formed on the anti-reflective coating. The first light conversion layer absorbs a first light with a first wavelength and emits a second light with a second wavelength, thereby performing a photoelectric converting operation. The second light conversion layer is formed on a second side of the semiconductor substrate. The second light conversion layer absorbs a third light with a third wavelength and emits a fourth light with a fourth wavelength, thereby performing another photoelectric converting operation.

The above contents of the present invention will become more readily apparent to those ordinarily skilled in the art after reviewing the following detailed description and accompanying drawings, in which:

### BRIEF DESCRIPTION OF THE DRAWINGS

FIGS. 1A˜1D are schematic views illustrating a process of fabricating a solar cell according to prior art;

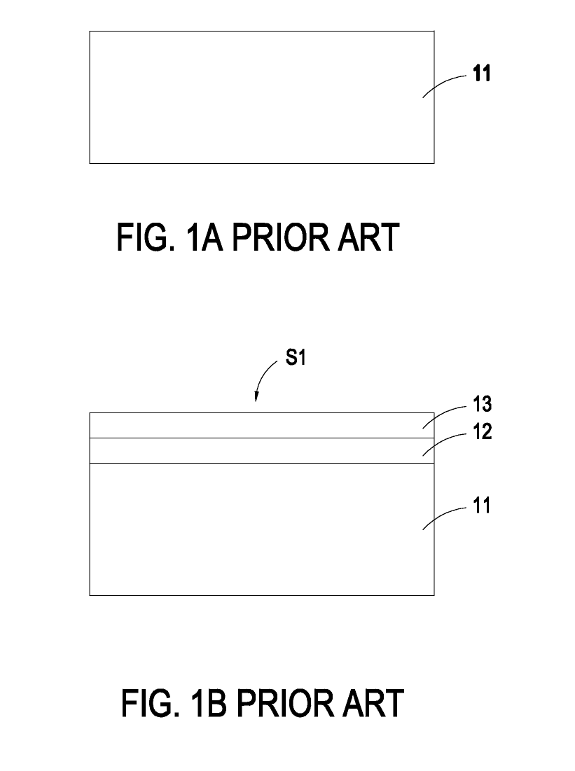

FIG. 2 is a schematic view illustrating a solar cell according to a first embodiment of the present invention;

FIG. 3 is a schematic view illustrating a solar cell according to a second embodiment of the present invention;

FIG. 4 is a schematic view illustrating a solar cell according to a third embodiment of the present invention; and

FIG. 5 is a schematic view illustrating a solar cell according to a fourth embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

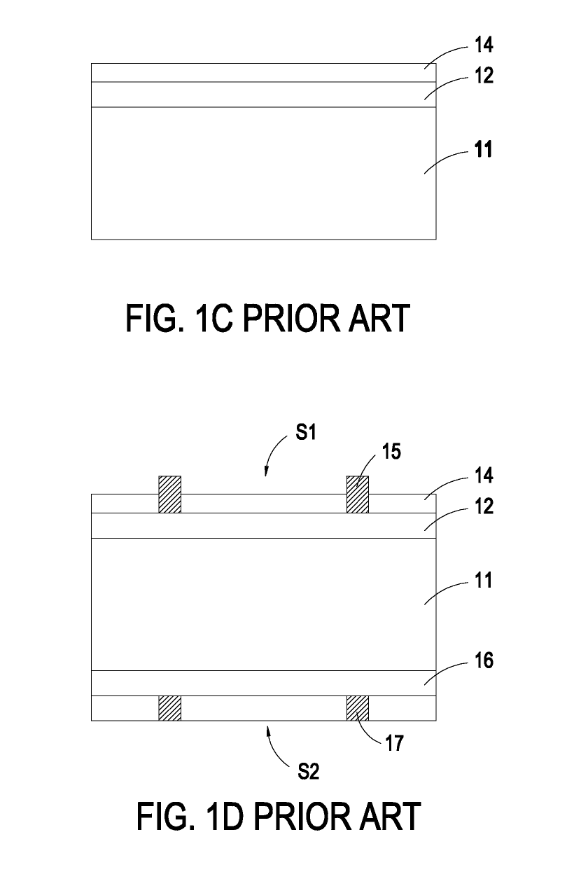

FIG. 2 is a schematic view illustrating a solar cell according to a first embodiment of the present invention. The solar cell 2 of the FIG. 2 is a monofacial solar cell that accepts sunlight from the light-receiving side S1 (or front side) and converts the light energy into electrical energy. The solar cell 2 comprises an encapsulation layer 27, a first electrode 24, a first light conversion layer 26, an anti-reflective coating 22, an emitter layer 21, a semiconductor substrate 20, a back surface field layer 20′, a second conductor layer 23 and a second electrode 25.

Similarly, concave and convex patterns with a minute pyramidal shape called as a texture are formed on the surface of the semiconductor substrate 20 at the light-receiving side S1 in order to improve light absorption and reduce light reflectivity. The texture structure is very minute and thus not shown in FIG. 2. The texture is formed by a wet etching procedure or a reactive ion etching. An example of the semiconductor substrate 20 includes but is not limited to a p-type semiconductor substrate.

Please refer to FIG. 2 again. The emitter layer 21 is formed on the light-receiving side S1 of the semiconductor substrate 20. In this embodiment, the emitter layer 21 includes but is not limited to an n-type emitter layer, which is formed by diffusing an n-type dopant source into the semiconductor substrate 20 at high temperature and creating a p-n junction between the semiconductor substrate 20 and the emitter layer 21. In addition, a phosphosilicate glass (PSG) layer (not shown) is formed on the emitter layer 21. Since the PSG layer is removed by an etching procedure, the PSG layer is not shown in FIG. 2. After the PSG layer is removed, the emitter layer 21 is exposed. The anti-reflective coating 22 is deposited on the emitter layer 21. The anti-reflective coating 22 is made of for example silicon nitride (SiNx). The use of the anti-reflective coating 22 can reduce light reflectivity, increase the permeability and passivate the emitter layer 21. As a consequence, a great quantity of hydrogen atoms can permeate through the anti-reflective coating 22 into the semiconductor substrate 20 and a hydrogen passivation process is carried out. The hydrogen passivation process is helpful to increase the performance of the solar cell 2. In some embodiments, the anti-reflective coating 22 is formed by a plasma enhanced chemical vapor deposition (PECVD) process. The anti-reflective coating 22 is made of silicon nitride, silicon dioxide, titanium dioxide, zinc oxide, tin oxide, magnesium dioxide, or the like.

The second conductor layer 23 is formed on the back-lighted side S2 (or back side) of the semiconductor substrate 20 by a screen printing process. In this embodiment, the second conductor layer 23 is made of a metallic material, which includes but is not limited to aluminum or silver. In addition, a first conductor layer (not shown) is formed on the anti-reflective coating 22 at the light-receiving side S1 of the semiconductor substrate 20 by a screen printing process. The first conductor layer is made of a metallic material, which includes but is not limited to silver. Next, by firing the first conductor layer, the first electrode 24 is formed on the light-receiving side S1. The first electrode 24 runs through the anti-reflective coating 22 and extends to be connected with the emitter layer 21. Due to the thermal conduction of the second conductor layer 23, the back surface field layer 20′ is formed between the semiconductor substrate 20 and the second conductor layer 23. At the same time, a portion of the second conductor layer 23 is formed into the second electrode 25 at the back-lighted side S2. The photoelectric converting operation is performed in the semiconductor structure 28, which is collectively defined by the first electrode 24, the anti-reflective coating 22, the emitter layer 21, the semiconductor substrate 20, the back surface field layer 20′, the second conductor layer 23 and the second electrode 25.

Please refer to FIG. 2 again. After the first electrode 24 and the second electrode 25 are formed, a layer of wavelength conversion material is applied on the anti-reflective coating 22. By baking the light-receiving side S1, the layer of wavelength conversion material is transformed into a first light conversion layer 26. The baking process is carried out at a temperature of 130° C. for example. The baking temperature is varied according to the practical requirements. The first light conversion layer 26 absorbs a first light with a first wavelength and emits a second light with a second wavelength. The wavelength conversion material constituting the first light conversion layer 26 is for example a phosphor. The refractive index of the wavelength conversion material is ranged between the refractive index of silicon nitride (SiNx) and the refractive index of glass. In addition, the wavelength conversion material is able to convert a shorter-wavelength light into a longer-wavelength light, or convert a longer-wavelength light into a shorter-wavelength light. In this embodiment, the first light conversion layer 26 disposed on the light-receiving side S1 of the solar cell 2 is made of a phosphor, which includes but is not limited to barium magnesium aluminate (BAM), cadmium telluride (CdTe), lanthanum phosphate (LaPO₄), or the like. When the first light conversion layer 26 absorbs light at the light-receiving side S1 of the solar cell 2, the shorter-wavelength UV light is subject to a down conversion (DC) process and thus a longer-wavelength light is emitted. For example, the first light conversion layer 26 can convert a first light with a first wavelength (e.g. 300 nm) into a second light with a second wavelength (e.g. 450 nm˜500 nm). In other words, the UV light that originally fails to be utilized by the conventional solar cell can be adjusted to be within a usable wavelength range (e.g. 400 nm˜1100 nm), so that the performance of the solar cell 2 is enhanced.

Please refer to FIG. 2 again. An encapsulation layer 27 is formed on the first light conversion layer 26. An additional encapsulation layer 27 is formed on the second conductor layer 23 at the back-lighted side S2. The encapsulation layer 27 is made of a transparent material such as glass. That is, the encapsulation layer 27 is formed on the external surface of the semiconductor structure 28 in order to protect the semiconductor structure 28. After the solar cell 2 is produced, the sunlight can be transmitted to the first light conversion layer 26 through the encapsulation layer 27, so that the shorter-wavelength light is converted into the longer-wavelength light. After the wavelength of the incident light is increased in effective range, the further photoelectric converting operation is performed and thus the performance of the solar cell 2 is enhanced.

An alternative process can be performed to manufacture the above structure. For example, the encapsulation layer 27 may include glass and adhesive layer such as EVA layer. The first light conversion layer 26 is coated on the adhesive layer, and then the combined structure of the encapsulation layer 27 and the first light conversion layer 26 is covered on the semiconductor structure 28, so that the first light conversion layer 26 is also interposed between the anti-reflective coating 22 and the encapsulation layer 27.

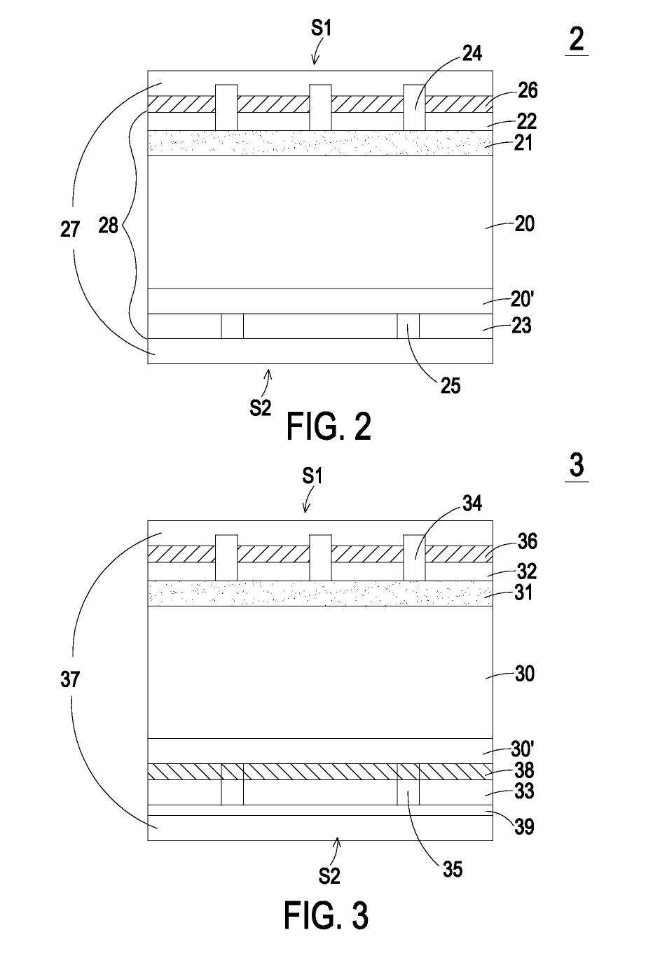

FIG. 3 is a schematic view illustrating a solar cell according to a second embodiment of the present invention. The solar cell 3 of FIG. 3 is also a monofacial solar cell that accepts sunlight from the light-receiving side S1 and converts light energy into electrical energy. From top to bottom, the solar cell 3 comprises an encapsulation layer 37, a first electrode 34, a first light conversion layer 36, an anti-reflective coating 32, an emitter layer 31, a semiconductor substrate 30, a back surface field layer 30′, a second conductor layer 33, a second electrode 35, a second light conversion layer 38, a reflective layer 39 and another encapsulation layer 37. The configurations, functions and production processes of the encapsulation layer 37, the first electrode 34, the first light conversion layer 36, the anti-reflective coating 32, the emitter layer 31, the semiconductor substrate 30, and the back surface field layer 30′ are similar to those illustrated in the first embodiment, and are not redundantly described herein. In this embodiment, after the grids of second electrode 35 are formed on the back-lighted side S2, a layer of wavelength conversion material is applied on the back surface field layer 30′ and filled in the grids of second electrode 35. By baking the back-lighted side S2 at a temperature of 130° C. for example, the layer of wavelength conversion material is transformed into the second light conversion layer 38. Then the second conductor layer 33 is formed on the second light conversion layer 38 and connected with the second electrode 35. Afterwards, a reflective layer 39, such as metal glue, is formed on the back-lighted side S2. The wavelength conversion material is an up-conversion material. When the second light conversion layer 38 absorbs light, the longer-wavelength IR light is subject to an up conversion (UC) process and thus a shorter-wavelength light is emitted.

In this embodiment, the first light conversion layer 36 is disposed on the light-receiving side S1 of the solar cell 3. When the first light conversion layer 36 absorbs light at the light-receiving side S1 of the solar cell 3, the shorter-wavelength UV light is subject to a down conversion (DC) process and thus a longer-wavelength light is emitted. The longer-wavelength light is transmitted downwardly so as to perform a photoelectric converting operation. The longer-wavelength light within the IR-spectral range fails to be directly used in the photoelectric converting operation but is continuously transmitted to the second light conversion layer 38 through the semiconductor structure. The longer-wavelength IR light is absorbed by the second light conversion layer 38, and thus a usable shorter-wavelength light is emitted. The usable shorter-wavelength light is reflected into the semiconductor structure to be subject to a photoelectric converting operation. Since the shorter-wavelength UV light is subject to a down conversion (DC) process by the first light conversion layer 36 and the longer-wavelength IR light is subject to an up conversion (UC) process by the second light conversion layer 38, the incident light received by the solar cell 3 can have a broader spectral range. As such, the performance of the solar cell 3 is largely enhanced.

Alternatively, the encapsulation layer 37 may include glass and adhesive layer such as EVA layer. The first light conversion layer 36 is coated on the adhesive layer, and then the combined structure of the encapsulation layer 37 and the first light conversion layer 36 is covered on the semiconductor structure, so that the first light conversion layer 36 is also interposed between the anti-reflective coating 32 and the encapsulation layer 37.

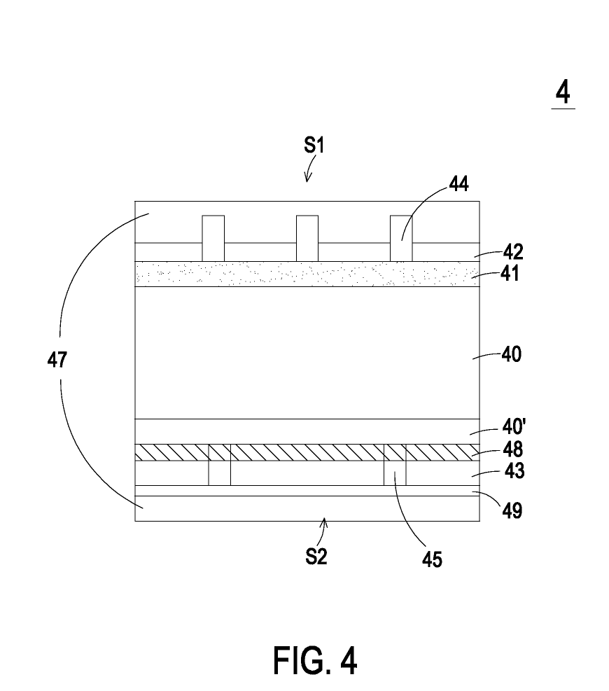

FIG. 4 is a schematic view illustrating a solar cell according to a third embodiment of the present invention. The solar cell 4 of the FIG. 4 is also a monofacial solar cell that accepts sunlight from the light-receiving side Si and converts light energy into electrical energy. From top to bottom, the solar cell 4 comprises an encapsulation layer 47, a first electrode 44, an anti-reflective coating 42, an emitter layer 41, a semiconductor substrate 40, a back surface field layer 40′, a second conductor layer 43, a second electrode 45, a second light conversion layer 48, a reflective layer 49 and another encapsulation layer 47. The configurations, functions and production processes of the encapsulation layer 47, the first electrode 44, the anti-reflective coating 42, the emitter layer 41, the semiconductor substrate 40, the back surface field layer 40′, the second conductor layer 43 and the second electrode 45 are similar to those illustrated in the above embodiments, and are not redundantly described herein.

In this embodiment, the second light conversion layer 48 is formed on the back-lighted side S2 of the solar cell 4. The wavelength conversion material of the second light conversion layer 48 includes but is not limited to an up-conversion phosphor, so that the longer-wavelength IR light can be subject to an up conversion (UC) process and thus a shorter-wavelength light is emitted. Therefore, in this embodiment, when the sunlight is transmitted to the second light conversion layer 48 through the interior of the solar cell 4, the longer-wavelength IR light is absorbed by the second light conversion layer 48, and thus a usable shorter-wavelength light is emitted. The usable shorter-wavelength light is reflected into the interior of the solar cell 4 to be subject to a photoelectric converting operation. Since the use of the second light conversion layer 48 can increase the efficiency of utilizing the longer-wavelength IR light, the performance of the solar cell 4 is enhanced.

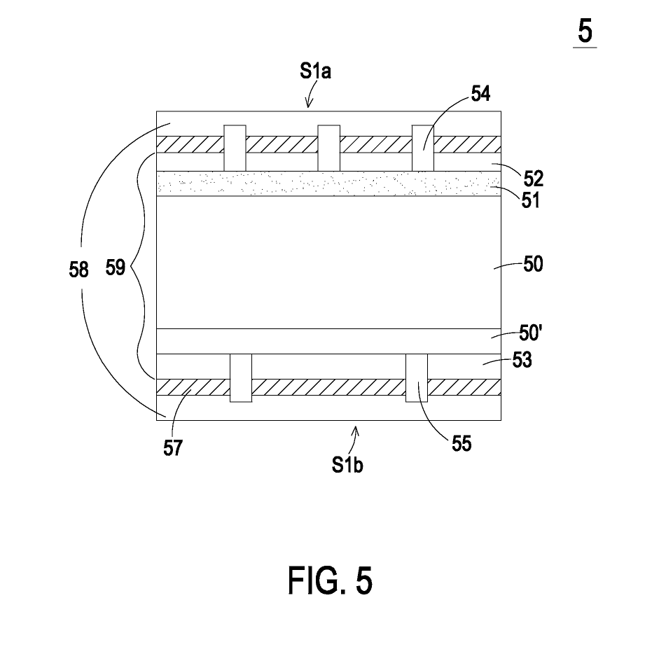

FIG. 5 is a schematic view illustrating a solar cell according to a fourth embodiment of the present invention. The solar cell 5 of FIG. 5 is a bifacial solar cell that accepts sunlight from the first light-receiving side S1a and/or the second light-receiving side S1b and converts light energy into electrical energy. The solar cell 5 comprises an encapsulation layer 58, a first electrode 54, a first light conversion layer 56, a first anti-reflective coating 52, an emitter layer 51, a semiconductor substrate 50, a back surface field layer 50′, a second anti-reflective coating 53, a second electrode 55, and a second light conversion layer 57. The configurations, functions and production processes of the encapsulation layer 58, the first electrode 54, the first light conversion layer 56, the first anti-reflective coating 52, the emitter layer 51, the semiconductor substrate 50 and the second light conversion layer 57 are similar to those illustrated in the above embodiments, and are not redundantly described herein.

Since the solar cell 5 is a bifacial solar cell, the configurations and the production processes of the back surface field layer 50′ and the second anti-reflective coating 53 at the second light-receiving side S1b are similar to the emitter layer 51 and the first anti-reflective coating 52 at the first light-receiving side S1a, and are not redundantly described herein.

Moreover, since the solar cell 5 is a bifacial solar cell, the first light conversion layer 56 covered on the first anti-reflective coating 52 and the second light conversion layer 57 covered on the second anti-reflective coating 53 are both made of down-conversion materials. The first light conversion layer 56 and the second light conversion layer 57 can convert the shorter-wavelength light that originally fails to be utilized by the conventional solar cell into a usable longer-wavelength light. The usable shorter-wavelength light is reflected into the semiconductor structure 59 to be subject to a photoelectric converting operation. Since the amount of incident light received by the solar cell 5 is increased and the shorter-wavelength light is adjusted to be within a usable wavelength range, the performance of the solar cell 5 is largely enhanced.

From the above description, the light conversion layer of the solar cell of the present invention absorbs a first light with a first wavelength and emits a second light with a second wavelength, thereby performing a photoelectric converting operation. In a case that the light conversion layer is made of a down-conversion material, the light conversion layer is disposed on the double light-receiving sides. Since the incident light received by the solar cell can have a broader spectral range, the performance of the solar cell of the present invention is largely enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A solar cell comprising:
a semiconductor substrate;
an emitter layer formed on a light-receiving side of said semiconductor substrate, wherein a p-n junction is formed between said emitter layer and said semiconductor substrate;
an anti-reflective coating formed on said emitter layer;
a first electrode connected to said emitter layer;
a second electrode formed on a back-lighted side of said semiconductor substrate; and
a first light conversion layer formed on said anti-reflective coating, wherein said first light conversion layer absorbs a first light with a first wavelength and emits a second light with a second wavelength, thereby performing a photoelectric converting operation.

2. The solar cell according to claim 1 further comprising a back surface field layer, which is formed between and connected with said semiconductor substrate and said second electrode.

3. The solar cell according to claim 1 further comprising an encapsulation layer, which is made of a transparent material.

4. The solar cell according to claim 3 wherein said transparent material includes glass.

5. The solar cell according to claim 3 wherein said encapsulation layer is formed on said first light conversion layer.

6. The solar cell according to claim 1 wherein said first light conversion layer is made of a down-conversion phosphor.

7. The solar cell according to claim 1 further comprising a second light conversion layer formed on a back-lighted side of said semiconductor substrate.

8. The solar cell according to claim 7 wherein said second light conversion layer is made of an up-conversion phosphor.

9. A solar cell comprising:
a semiconductor substrate;
an emitter layer formed on a light-receiving side of said semiconductor substrate, wherein a p-n junction is formed between said emitter layer and said semiconductor substrate;
an anti-reflective coating formed on said emitter layer;
a first electrode connected to said emitter layer;
a second electrode formed on a back-lighted side of said semiconductor substrate; and
a second light conversion layer formed on said back-lighted side of said semiconductor substrate, wherein said second light conversion layer absorbs a first light with a first wavelength and emits a second light with a second wavelength, thereby performing a photoelectric converting operation.

10. The solar cell according to claim 9 further comprising a back surface field layer, which is formed between and connected with said semiconductor substrate and said second electrode.

11. The solar cell according to claim 9 further comprising an encapsulation layer, which is made of a transparent material.

12. The solar cell according to claim 11 wherein said transparent material includes glass.

13. The solar cell according to claim 11 wherein said encapsulation layer is formed on said second light conversion layer.

14. The solar cell according to claim 9 wherein said second light conversion layer is made of an up-conversion phosphor.

15. A bifacial solar cell comprising:
a semiconductor substrate;
an emitter layer formed on a first side of said semiconductor substrate, wherein a p-n junction is formed between said emitter layer and said semiconductor substrate;
an anti-reflective coating formed on said emitter layer;
a first electrode connected to said emitter layer;
a second electrode connected to said semiconductor substrate;
a first light conversion layer formed on said anti-reflective coating, wherein said first light conversion layer absorbs a first light with a first wavelength and emits a second light with a second wavelength, thereby performing a photoelectric converting operation; and
a second light conversion layer formed on a second side of said semiconductor substrate, wherein said second light conversion layer absorbs a third light with a third wavelength and emits a fourth light with a fourth wavelength, thereby performing another photoelectric converting operation.

16. The bifacial solar cell according to claim 15 further comprising a back surface field layer, which is formed between and connected with said semiconductor substrate and said second electrode.

17. The bifacial solar cell according to claim 15 further comprising an encapsulation layer, which is made of a transparent material.

18. The bifacial solar cell according to claim 17 wherein said transparent material includes glass.

19. The bifacial solar cell according to claim 17 wherein said encapsulation layer is formed on said first light conversion layer and said second light conversion layer.

20. The bifacial solar cell according to claim 15 wherein said first light conversion layer and said second light conversion layer are made of down-conversion phosphors.
